(19) United States
(12) Patent Application Publication
(10) Pub. No.: US 2011/0062970 A1
(43) Pub. Date: Mar. 17, 2011

(54) Rotating Angle Detection Device Used Capacitive Change and Method Thereof

(76) Inventors: Mi Kyung Kim, Daejeon (KR); Rae Duk Lee, Daejeon (KR); Dong Seok Kim, Daejeon (KR)

(21) Appl. No.: 12/991,323

(22) PCT Filed: May 8, 2008
(86) PCT No.: PCT/KR08/02596

§ 371 Date: Nov. 5, 2010

(51) Int. Cl. G01R 27/26

(52) U.S. Cl. 324/658

(57) ABSTRACT

This invention can increase the resolving power of the rotating angle using the rate of capacity change between two objects. The objective is to provide a rotating angle detecting device using capacitive change that is small in size and costs low to manufacture. The method to reach the above objective is a rotating angle detection device with a stator with two fixed conductor plates; and a rotator with a rotating conductor plate that rotates relatively to the above stator, with every rotation overlapping and passing the above fixed conductor plates repeatedly with different area change.

### TECHNICAL FIELD

Components of the electrical system used in our daily lives are resistance, inductance and capacitance. Measurements of these three components can be used to analyze the electrical current, voltage and electrical power at each position in the electrical system. Of these three components, capacitance occurs when electrical power between two mediums exists. Capacitance can be used to measure the angle of a rotating device.

### BACKGROUND ART

When electrical power is delivered between two conductors, capacitance is created between the two conductors. The size of the capacitance is in inverse proportion to the distance between the two conductors, and is proportionate to the rate of the induced electricity of the dielectric substance between the two conductors, and also to the area size of the conductors.

### DISCLOSURE

### Technical Problem

This invention is about a device to measure the rotating angle of a rotating object In particular, it is about a rotating angle detection device that detects the rotating angle using the change in capacitive rate between conductors that intersect through rotation.

Up until now, in order to measure the rotating angle of a rotating object, a mechanical encoder composed of a rotating valve with slit holes at fixed intervals, a radiating device placed to the side of the above rotating device, and photo detector that is placed to the side of the above rotating device and receives light signals that pass through the slit holes was used.

However, in the instance of using the mechanical encoder, in order to increase the resolving power of the angle, the slit holes must be either small in size or must be arranged at close intervals. But because of physical restraints, making the slit holes small or arranging the slit holes densely is difficult, therefore making the increase of rotating angle's resolving power difficult.

Also, in the case of the method using mechanical encoding, problems exist of having a relatively high manufacturing cost.

### Technical Solution

Therefore, this invention was created taking the above circumstances into account. Using 2 changes in the capacitive rate, it is possible to increase the resolving power of the rotating angle. The objective is to provide a rotating angle detection device and method using capacitive change that can be created small and inexpensively.

### ADVANTAGEOUS EFFECTS

As stated above, in this invention of rotating angle detection device using capacitive change, because there is no need to create slit holes in the rotating valve, it can be created small in size and cut down on the manufacturing costs. Also, because this invention shaped rotating angle also has conversion value through capacitive rate, another advantage is that it is possible to gain high resolving power of the angle detection.

### DESCRIPTION OF DRAWINGS

The following drawings in this account are examples of the invention's desirable use. The drawings, along with detailed descriptions of the invention that will follow, will help with better understanding the invention. Therefore, this invention should not be limited to what is stated on the drawings.

FIG. 1 shows a real drawing of a stator and a rotator that is applied to this invention's number 1 application example.

FIG. 2 shows a construction state drawing of the stator and rotator that is applied to this invention's number 1 application example.

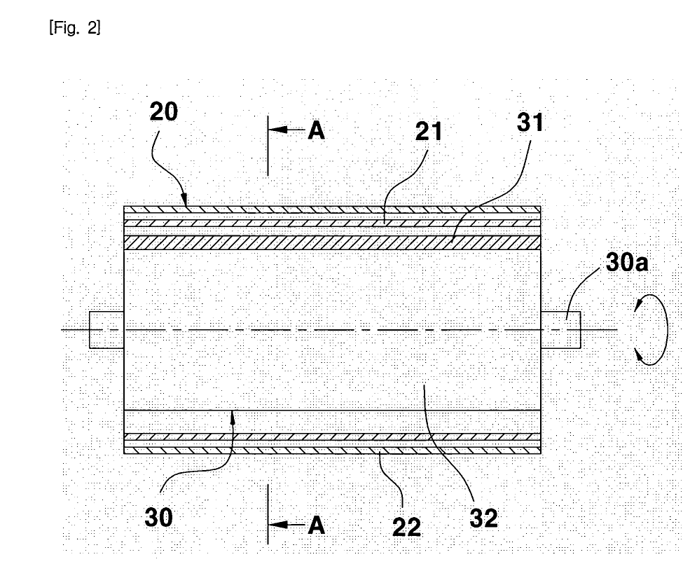

FIG. 3 shows the sectional view of FIG. 1 from the A-A line.

FIG. 4 shows the interior development figure of the conductor plate that are fixed that is applied this invention's number 1 application example.

FIG. 5 shows the development figure of the conductor plate that is able to rotate that is applied to this invention's number 1 application example.

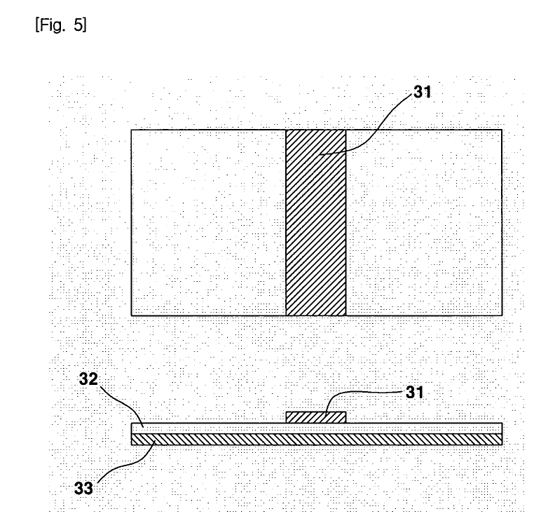

FIG. 6 shows the organization drawing of the rotating angle detecting device using capacitive change according to this invention's number 2 example.

FIG. 7 shows the plane organization drawing of the fixed and conductor plate that is able to rotate that is applied to this invention's number 2 example.

### BEST MODE

The concrete methods to accomplish the above goals are as follows:
the rotating angle detection device is composed of a stator with two conductor plate that are fixed,
and a rotator with a rotating conductor plate that rotates relatively to the above stator, with every rotation overlapping and passing the above conductor plate that are fixed repeatedly with different area change.

Also, according to this invention, the components also include a capacitance digital converter that is connected electrically to the above fixed conductor plate and converts different analogue figures of capacitance into digital angles.

Also, according to this invention, the above fixed two conductor plates have a characteristic of being composed in a right triangle or a taegeuk shape.

Also, according to this invention, the components also include a dielectric substance that can increase capacity by increasing the induced electricity rate between the above conductor plates that are fixed and the conductor plate that is able to rotate.

Also, according to this invention, the above fixed conductor plates and the rotating conductor plate have a characteristic of having an insulator and a shield on the back side.

Also, according to this invention, the method of detecting the rotating angle is:

Having two fixed conductor plates that are set up on the flat side or on all of the inside, and also a rotating conductor plate that intersects with the above conductor plates that are fixed with regular area and is able to rotate;

There is a phase of connecting the above conductor plate that is able to rotate to the rotating object;

The characteristics of detecting the rotating angle include the phase of using a capacitance digital converter to convert the converted value of each capacity (C1, C2) that occurs between the above two conductor plates that are fixed by rotating the above rotating conductor plate into a rotating angle that corresponds to the capacity rate (C1/(C2+C3)).

First, this invention applies the concept of the method of capacitive sensor, and detects the rotating degree (0°˜360°) by calculating the capacity ratio of the two, and transforming it into a fan shaped angle, in order gain high resolving power.

In other words, this invention is constituted so that the rotating conductor plate is connected to the axis of rotation overlaps and passes through the two fixed conductor plates at the same time, and making the ratio of the capacity that occurs in accordance with the change in area of the conductor plate that are fixed correspond by 360°.

Below there will be a description of this invention's application example, referring to the drawing that is attached.

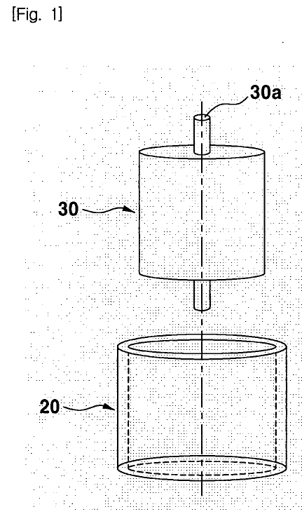

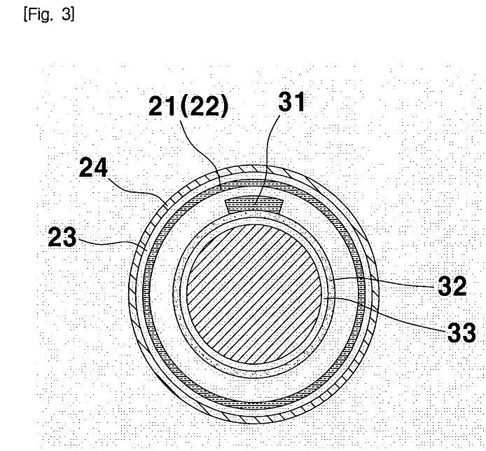

As seen in FIG. 1 or FIG. 3, the rotating angle detection device according to this invention is composed of a stator (20), and a rotator (30) that rotates relatively to the above stator.

In number 1 application example, the stator (20) is constituted in a cylinder shape, and the above rotator has a cylinder section and is inserted inside to above stator (20) and rotates. At this point, rotator (30) has an axis of rotation (30a) to receive rotation power from the rotating device (not indicated).

The above stator (20) has two fixed conductor plates (21,22) that is divided on the inside.

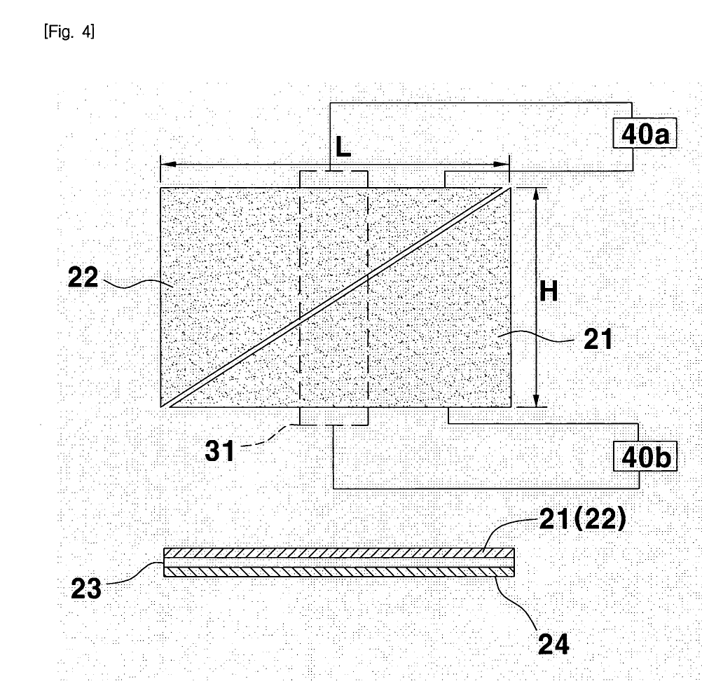

On this application example, the two fixed conductor plates (21,22) is made up of a right triangle shape that has a side with the same slope, as shown in FIG. 4.

At this point, on the back side of the above fixed conductor plates (21,22), a shield (24) is constituted out of the insulator (23). The shield (24) is set up in order to prevent electric field from the outside, or parasitic capacitance made by a magnetic field.

The above rotator (30) has a rotating conductor plate (31) that is placed on the number one spot on the outside and with every 1 rotation makes position change above the above fixed two conductor plates (21,22) and intersects and passes through with different area change.

Here, the rotating conductor plate (31) is made smaller than the length (L) of the fixed conductor plates (21,22) and equal to the width (H) of the fixed conductor plates (21,22).

Also, on the back side of the above rotating conductor plate (31), an insulator and a shield (33) is constituted. The shield (33) is set up in order to prevent armature from the outside, or parasitic capacitance made by a magnetic field.

Meanwhile, this invention is composed of an electrically connected capacitance digital converter (40a,40b) that converts the analogue measurement of the different capacity (C1,C2) that occurs between the above fixed conductor plates (21,22) and the above rotating conductor plate (31), into a digital angle.

In the rotating angle detection device in application example number 1 that is constituted as shown above, the axis of rotation (30a) of the rotator (30) is connected to the rotating device (not indicated).

In this state, when the rotator (30) rotates, the rotating conductor plate (31) passes through above the two fixed conductor plates (21,22) and overlaps with different area change. Therefore, with each rotation of the rotator (30), the area overlapping between the rotating conductor plate (31) and the fixed conductor plates (21,22) changes.

Because of this, with every rotation angle of the position of the rotating conductor plate (31), the capacity (C1,C2) between it and the fixed conductor plates (21,22) changes.

Therefore, as seen in the below table 1, when the width of the rotating conductor plate (31) is 10 mm, and the width circumference of the fixed conductor plates (21,22) is 31.4 mm (the circumference of a circle with a diameter of 10 mm) and the vertical length is 5 mm, it is shown that the capacitance (C1,C2) of the rotator (30) movement position changes in inverse proportion.

TABLE 1

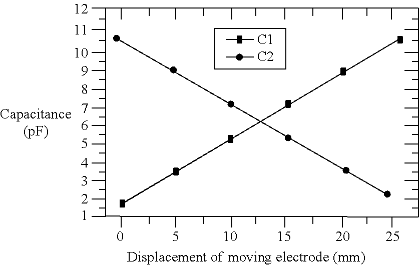

Also, when using the above capacitance (C1,C2) to plot the rate of the resolving power (C1/C1+C2), the results are as seen in table 2.

TABLE 2

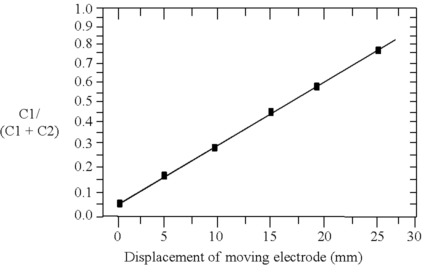

Therefore, each capacity is converted into a digital value by the capacitance digital converter (40a,40b) that is connected to the above fixed conductor plates (21,22) and the rotating conductor plate (31), and from this the ratio of C1/(C1+C2) is obtained and the corresponding rotating angle (0°˜360°) to it is converted.

Meanwhile, a dielectric substance can be set up between the above fixed conductor plates (21,22) and the rotating conductor plate (31) in order to increase the resolving power by elevating the induced electricity rate (∈ᵣ).

In general, capacitance, C is defined as below. Therefore, in this invention, the rotating angle resolving power can be increased by increasing the area (A) of the conductor plate, decreasing the thickness (d) of the dielectric substance, or using a dielectric substance with high inducted electricity rate (∈r).

$$C = {ɛ}_{0} {ɛ}_{r} \frac{A}{d}$$

Here, the ∈ᵣ is the inducted electricity rate in an infinite space.

### MODE FOR INVENTION

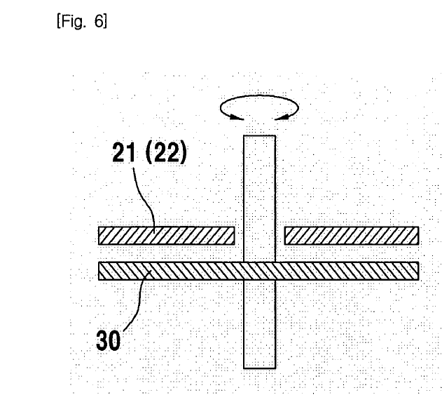

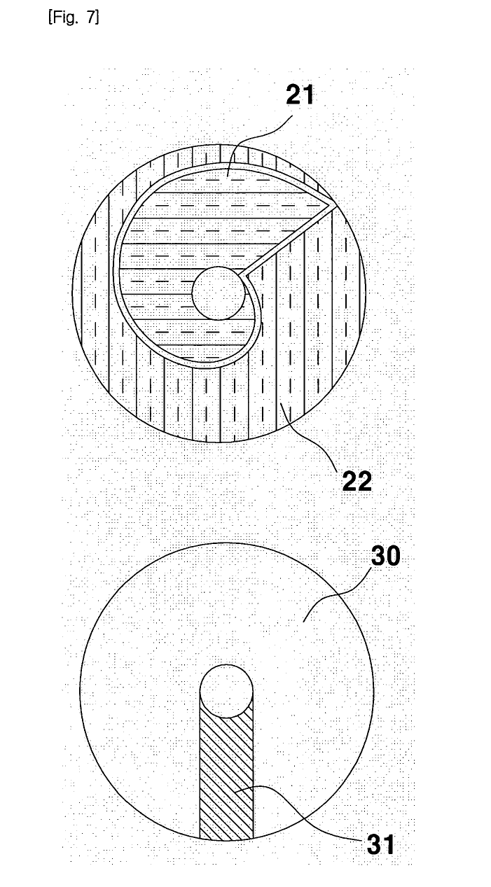

Meanwhile, this invention is the number 2 application example of its modified example, and as seen in FIG. 6 and FIG. 7, the stator (20) and the rotator (30) is constituted in a circular plate shape. Here, the two fixed conductor plates (21,22) have the characteristic of being constituted in a modified spiral shape of a right triangle.

The effects of this are the same as in application example number 1, so a detailed description will be omitted.
As above, even though this invention was described in limited application examples and drawings, the invention itself is not limited to them. This invention can be adjusted and modified in the range of the technology of this invention and the below uniform applications by a person with general knowledge in the technology field where this invention belongs.

### INDUSTRIAL APPLICABILITY

In our daily lives, the problem of calculating the exact rotating angle or the position between two objects is very important. For example, the problem of combining two objects automatically from remote distances is very difficult, requiring the position and the rotating angle between the two objects. Using the technology of this invention will provide a simple and easy solution.

1. A rotating angle detection device comprising:
a stator (20) with two conductor plates (21,22) that are fixed;
a rotator (30) with a conductor plate (31) that is able to rotate relatively to the said stator (20), with every rotation overlapping and passing the above fixed conductor plates (21,22) repeatedly with different area change.

2. The rotating angle detection device of claim 1 wherein the rotating angle detection device further comprises a capacitance digital converter (40a,40b) that is connected electrically to the said fixed conductor plate (21,22) and the rotating conductor plate (31) and converts different analogue figures of capacitance into digital angles.

3. The rotating angle detection device of claim 1 wherein two conductor plates (21,22) further comprises opposite right triangle shapes each in order to make the area rate depending on position as high as possible.

4. The rotating angle detection device of claim 1 wherein two conductor plates (21,22) comprise a modified spiral shape of a right triangle.

5. The rotating angle detection device of claim 1 wherein the rotating angle detection device further comprises a dielectric substance that can increase capacity by increasing the induced electricity rate between the said fixed conductor plates (21,22) and the rotating conductor plate (31).

6. The rotating angle detection device of claim 1 wherein the conductor plate further comprises a rotating conductor plate (31) having an insulator (23) and a shield (24) on the back side.

7. A method of detecting the rotating angle comprising the steps of,
a. Having two fixed conductor plates that is set up on the flat side or on all of the inside, and also a rotating conductor plates that faces and intersects with the said fixed conductor plates with regular area;
b. connecting the above rotating conductor plate to the rotating object;
c. detecting a rotating angle by using a capacitance digital converter to convert the converted value of each capacity (C1, C2) that occurs between the said two fixed conductor plates by rotating the said rotating conductor plate into a rotating angle that corresponds to the capacity rate (C1/(C2+C3)).
